(19) United States
(12) Patent Application Publication
(10) Pub. No.: US 2025/0221016 A1
(43) Pub. Date: Jul. 3, 2025

(54) INTEGRATED DEVICE AND PREPARATION METHOD THEREOF

(71) Applicant: HUNAN SAN’AN SEMICONDUCTOR CO.,LTD., Changsha (CN)

(72) Inventors: Shengnan JI, Changsha (CN); NIEN TZE YEH, Changsha (CN); Cheng LIU, Changsha (CN); Han XU, Changsha (CN); Zheli Wang, Changsha (CN); Yuyu Liang, Changsha (CN)

(21) Appl. No.: 18/820,273

(22) Filed: Aug. 30, 2024

(30) Foreign Application Priority Data
Dec. 28, 2023 (CN) 202311854032.3

(51) Int. Cl. H01L 27/07; H01L 29/20; H01L 29/66; H01L 29/778; H01L 29/872

(52) U.S. Cl. CPC H10D 84/811; H10D 8/051; H10D 8/60; H10D 30/015; H10D 30/475; H10D 62/8503

(57) ABSTRACT

An integrated device and a preparation method thereof are provided. The integrated device includes: a substrate; a compound semiconductor composite structure disposed on the substrate; a first component including a first electrode and second electrodes disposed on two sides of the first electrode; a second component including a gate electrode, and a source electrode and a drain electrode that are disposed on two sides of the gate electrode. The first electrode and the gate electrode are spaced apart on the compound semiconductor composite structure. The integrated device further includes an n-type nitride layer including a first n-type nitride layer disposed between the compound semiconductor composite structure and the first electrode; and a p-type nitride layer disposed between the compound semiconductor composite structure and the gate electrode. The integrated device improves its properties, a threshold voltage thereof is reduced, and turn-on power consumption thereof is reduced.

### CROSS-REFERENCE TO RELATED APPLICATION

This application claims priority to a Chinese patent application No. 202311854032.3, filed to China National Intellectual Property Administration (CNIPA) on Dec. 28, 2023, which is herein incorporated by reference in its entirety.

### TECHNICAL FIELD

The present disclosure relates to the field of semiconductor technologies, and more particularly to an integrated device and a preparation method thereof.

### BACKGROUND

Third-generation wide bandgap semiconductor materials and devices are developed to promote overall properties of power integrated circuits. At present, a monolithic integration method is commonly used for integrating a power diode and other discrete components in the same device, which is suitable for batch production, and has the advantages of being small in size and being light in weight. However, an energy loss of the obtained integrated device mainly comes from a turn-on voltage drop loss in a turn-on process of the power diode. Moreover, the power diode has a large turn-on loss, resulting that the performance of the integrated device is poor and some benefits of the monolithic integration are offset.

### SUMMARY

In order to solve some or all of the above-mentioned problems, the present disclosure provides an integrated device and a preparation method thereof. The integrated device can reduce a threshold voltage, so that a gate voltage with a small range can effectively turn on the integrated device, can reduce the power consumption during turning on the integrated device, and can improve the stability of the integrated device.

According to a first aspect of the present disclosure, the integrated device is provided, including: a substrate; a compound semiconductor composite structure disposed on the substrate and configured to generate a two-dimensional electron gas; a first component including a first electrode and second electrodes disposed on two sides of the first electrode; and a second component including a gate electrode, a source electrode, and a drain electrode. The source electrode and the drain electrode are disposed on two sides of the gate electrode, and the first electrode and the gate electrode are spaced apart on the compound semiconductor composite structure. The integrated device further includes a negative-type (n-type) nitride layer, including a first n-type nitride layer disposed between the compound semiconductor composite structure and the first electrode; and a positive-type (p-type) nitride layer disposed between the compound semiconductor composite structure and the gate electrode.

According to a second aspect of the present disclosure, a Schottky diode is provided, including: a substrate; a compound semiconductor composite structure disposed on the substrate; a first electrode disposed on the compound semiconductor composite structure; and an n-type nitride layer disposed between the compound semiconductor composite structure and the first electrode.

According to a third aspect of the present disclosure, a method for preparing an integrated device is provided, including: providing a substrate, forming a compound semiconductor composite structure configured to generate a two-dimensional electron gas on the substrate; forming a first component and a second component on the compound semiconductor composite structure, where the first component includes a first electrode and second electrodes disposed on two sides of the first electrode; the second component includes a gate electrode, and a source electrode and a drain electrode that are disposed on two sides of the gate electrode; the first electrode and the gate electrode are spaced apart on the compound semiconductor composite structure; preparing an n-type nitride layer, which includes a first n-type nitride layer disposed between the compound semiconductor composite structure and the first electrode; and preparing a p-type nitride layer disposed between the compound semiconductor composite structure and the gate electrode.

In the Schottky diode, the integrated device and the preparation method thereof provided by the embodiments of the present disclosure, the n-type nitride layer is arranged on the first electrode and the compound semiconductor composite structure, which can reduce the threshold voltage of the integrated device, reduce the turn-on power consumption of the integrated device, and improve the properties of the integrated device.

### BRIEF DESCRIPTION OF DRAWINGS

The preferred embodiments of the present disclosure will be described in detail below with reference to the attached drawings.

FIG. 1 illustrates a schematic diagram of an integrated device according to some embodiments of the present disclosure.

FIG. 2 illustrates a schematic diagram of an integrated device according to some embodiments of the present disclosure.

FIGS. 3a to 3b illustrate schematic diagrams of an integrated device according to some embodiments of the present disclosure.

FIG. 4 illustrates a schematic diagram of an integrated device according to some embodiments of the present disclosure.

FIG. 5 illustrates a schematic diagram of an integrated device according to some embodiments of the present disclosure.

FIG. 6 illustrates a schematic diagram of a Schottky diode according to some embodiments of the present disclosure.

FIG. 7 illustrates a schematic diagram of a Schottky diode according to some embodiments of the present disclosure.

FIG. 8 illustrates a flowchart of a method for preparing an integrated device according to some embodiments of the present disclosure.

FIG. 9 illustrates a schematic diagram of preparing a compound semiconductor composite structure on a substrate according to the present disclosure.

FIG. 10a illustrates a schematic diagram of preparing a p-type nitride layer on the compound semiconductor composite structure according to the present disclosure.

FIG. 10b illustrates a schematic diagram of preparing a prefabricated p-type nitride layer on the compound semiconductor composite structure according to the present disclosure.

FIG. 11a illustrates a schematic diagram of preparing an n-type nitride layer according to the present disclosure.

FIG. 11b illustrates a schematic diagram of preparing a first prefabricated dielectric layer on the compound semiconductor composite structure according to the present disclosure.

FIG. 11c illustrates a schematic diagram of defining a first via and a second via on the first prefabricated dielectric layer according to the present disclosure.

FIG. 11d illustrates a schematic diagram of preparing a prefabricated n-type nitride layer on the first prefabricated dielectric layer according to the present disclosure.

FIG. 11e illustrates a schematic diagram of preparing a second prefabricated dielectric layer on the prefabricated n-type nitride layer according to the present disclosure.

FIG. 12a illustrates a schematic diagram of forming second electrodes, a source electrode, and a drain electrode according to the present disclosure.

FIG. 12b illustrates a schematic diagram of defining a first groove, a second groove, a third groove, and a fourth groove on the first prefabricated dielectric layer according to the present disclosure.

FIG. 13 illustrates a schematic diagram of preparing a first electrode and a gate electrode according to the present disclosure.

### DETAILED DESCRIPTION OF EMBODIMENTS

The present disclosure will be further described below with reference to the attached drawings.

In the description of the present disclosure, “preparing” refers to preparing a layer structure having a certain requirement on a to-be-processed material. Techniques related to “preparing” may include: physical vapor deposition (PVD) techniques commonly used for chip fabrication such as electron beam evaporation (also referred as to E-Gun evaporation), chemical vapor deposition, metal-organic chemical vapor deposition (MOCVD) commonly used for epitaxial growth, liquid phase epitaxy (LPE), vapor phase epitaxy (VPE), molecular beam epitaxy (MBE), atomic layer deposition (ALD), etc. For those skilled in the related art, appropriate preparation techniques may be selected according to actual situations.

In the description of the present disclosure, “etching” should be understood in a broad sense, that is, a layer of photoresist is grown on a surface of the to-be-processed material, and the photoresist is selectively exposed and developed through mask, so as to leave a photoresist layer having a same pattern as the mask on the surface of the to-be-processed material, then the to-be-processed material is selectively corroded by using a chemical or physical method, and finally the photoresist layer is stripped to form a structure corresponding to the pattern of the mask on the to-be-processed material.

In the description of the present disclosure, the orientation or position relationship indicated by “upper” or “lower” is based on the orientation or position relationship shown in the attached drawings, but is merely used to facilitate describing the present disclosure and simplify the description of the present disclosure, rather than indicating or implying that the device or element referred to has to have a specific orientation, and is constructed and operated in a specific orientation, and therefore cannot be understood as a limitation to the present disclosure.

In the description of the present disclosure, in addition to an embodiment 1, the other embodiments are written in a manner of avoiding duplication as much as possible, that is, descriptions different from those of other embodiments are recorded in detail. In these embodiments, any technical feature is not explicitly described, and reference may be made to the corresponding description of embodiment 1.

The illustrated embodiments of the present disclosure are described in detail below with reference to the attached drawings.

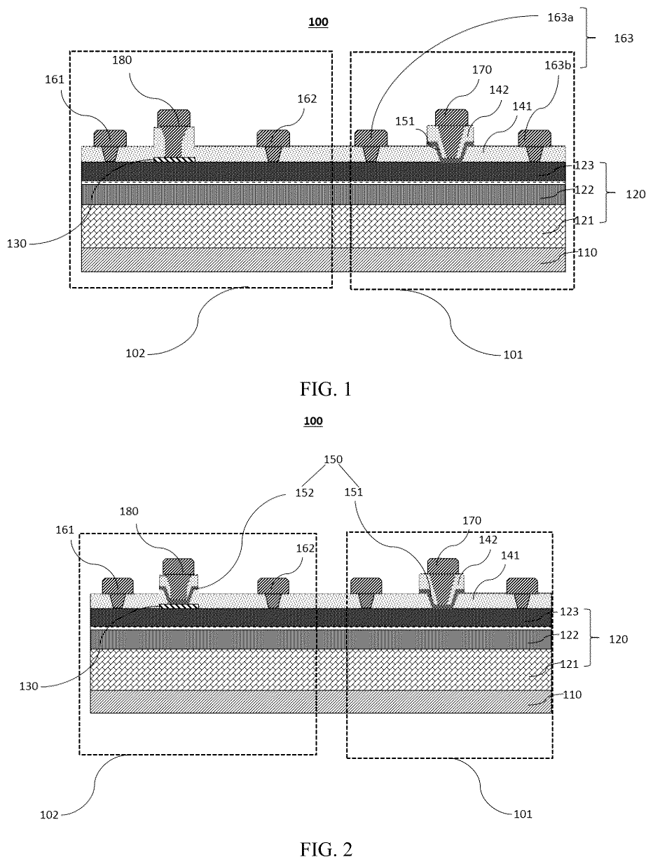

In an illustrated embodiment, referring to FIG. 1 and FIG. 2, an integrated device 100 includes: a substrate 110; a compound semiconductor composite structure 120 disposed on the substrate 110 and configured to generate a two-dimensional electron gas; a first component 101 including: a first electrode 170 and second electrodes 163 including the second electrode 163a and the second electrode 163b, where the second electrodes 163a and 163b are disposed on two sides of the first electrode 170; and a second component 102 including: a gate electrode 180, a source electrode 161, and a drain electrode 162, where the source electrode 161 and the drain electrode 162 are disposed on two sides of the gate electrode 180. The first electrode 170 and the gate electrode 180 are spaced apart on the compound semiconductor composite structure 120. The integrated device 100 further includes: a negative-type (n-type) nitride layer 150 that includes a first n-type nitride layer 151 disposed between the compound semiconductor composite structure 120 and the first electrode 170; and a positive-type (p-type) nitride layer 130 disposed between the compound semiconductor composite structure 120 and the gate electrode 180.

The substrate 110 can be one of various substrates such as a silicon substrate, a silicon carbide substrate, a gallium nitride substrate, a sapphire, a germanium substrate, a semiconductor on insulator (SOI, e.g., silicon-on-insulator, germanium-on-insulator, or silicon-germanium-on-insulator) substrate. Those skilled in the related art understand that the substrate is not limited, but can be selected according to practical applications, and specifically, in the present embodiment, the silicon substrate is taken as an example for description.

It should be noted that the nitride layer refers to a group III nitride, i.e., the wide bandgap semiconductor material, such as a gallium nitride (GaN), and an aluminum nitride (AlN). Specifically, the nitride layer of the present embodiment is described by using the GaN as an example.

It should be noted that the compound semiconductor composite structure 120 refers to an epitaxial structure, and may include a back barrier layer and/or a buffer layer 121 disposed on the substrate 110, a channel layer 122, and a barrier layer 123, and the two-dimensional electron gas disposed between the channel layer 122 and the barrier layer 123. The epitaxial structure can be designed by those skilled in the related art according to requirements of the integrated device 100.

The first n-type nitride layer 151 disposed between the compound semiconductor composite structure 120 and the first electrode 170 can reduce the threshold voltage of the first component 101, so that the integrated device 100 can be effectively turned on by a small gate voltage, which can reduce the power consumption of the integrated device 100 and improve the properties of the integrated device 100.

In some embodiments, the second component 102 is a high-electron-mobility transistor (HEMT). Specifically, the second component 102 is an enhanced HEMT. The first component 101 is a power diode. Specifically, the first component 101 is a Schottky diode, and more specifically, the first component 101 is a Schottky barrier diode (SBD). The first electrode 170 serves as an anode of the SBD, and the second electrodes 163a and 163b disposed on the two sides of the anode (i.e., the first electrode 170) serve as cathodes of the SBD. The SBD structure simplifies the process and better reduces costs for preparing the integrated device. The method of fabricating the enhanced HEMT and the SBD on the same silicon wafer in power electronic circuits not only has the advantages of being suitable for mass production, small in size, and light in weight, but also effectively reduces parasitic parameters after the integration of the two components, reducing losses while minimizing oscillations and increasing reliability.

In some embodiments, as shown in FIG. 2, the n-type nitride layer 150 further includes a second n-type nitride layer 152, and the second n-type nitride layer 152 is disposed between the p-type nitride layer 130 and the gate electrode 180.

The second n-type nitride layer 152 is set to form a heterojunction with the p-type nitride layer 130, thereby reducing the leakage of the integrated device 100 and enhancing the stability of the gate control.

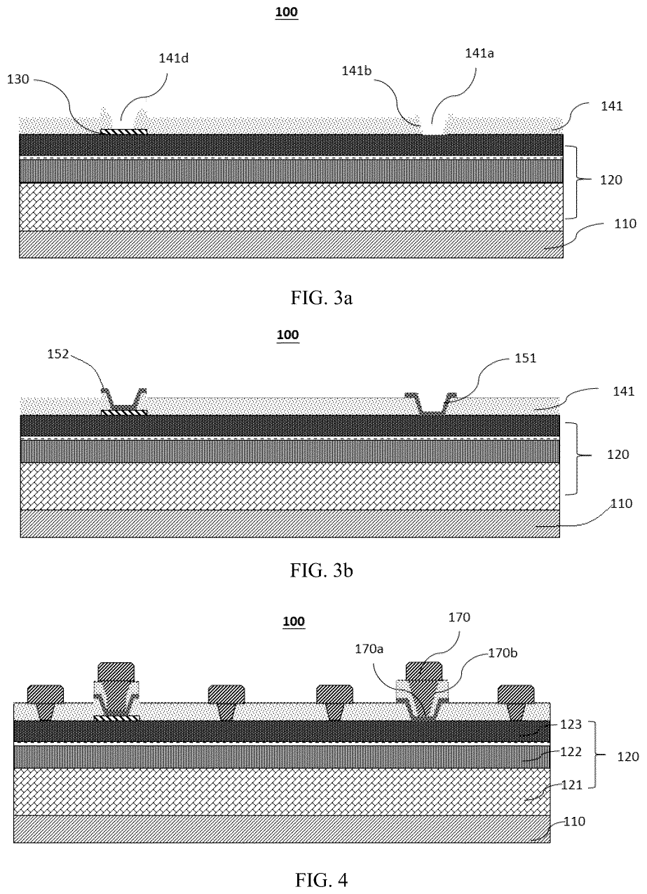

In some embodiments, as shown in FIGS. 3a-3b, the integrated device 100 further includes: a first dielectric layer 141 disposed on the compound semiconductor composite structure 120. The first dielectric layer 141 defines a first via 141a for accommodating the first electrode 170. The first via 141a is provided with two sidewalls 141b facing towards a surface of the compound semiconductor composite structure 120, and the first n-type nitride layer 151 extends from the two sidewalls 141b to the surface of the compound semiconductor composite structure 120 disposed in the first via 141a.

It should be noted that the two sidewalls 141b refer to the two sidewalls that are symmetrically disposed on a left side and a right side of the first via 141a, and only one sidewall on the right side is identified in the attached drawings.

In order to match the design of the existing HEMT and SBD integrated device, the first n-type nitride layer 151 is formed along the two sidewalls 141b of the first via 141a in the first via 141a defined on the first dielectric layer 141, which reduces changes in the process and reduces the cost of the integrated device. Moreover, it should be noted that those skilled in the related art can change the shape design of the first n-type nitride layer 151 according to the structural design and process requirements of the integrated device, as long as that the threshold voltage of the power diode can be reduced, and the conduction loss of the integrated device can be reduced.

In some embodiments, in order to save process steps, the n-type nitride layer 150 is molded in one step, the second n-type nitride layer 152 forms a second n-type gallium nitride having the same design as the first n-type nitride layer 151, and the second n-type nitride layer 152 is disposed between the gate electrode 180 of the second component 102 and the p-type nitride layer 130. It should be noted that those skilled in the related art may prepare different shapes of the second n-type nitride layer 152 according to different HEMT, so long as the heterojunction can be formed, the leakage of the integrated device is reduced, and the stability of gate control is enhanced.

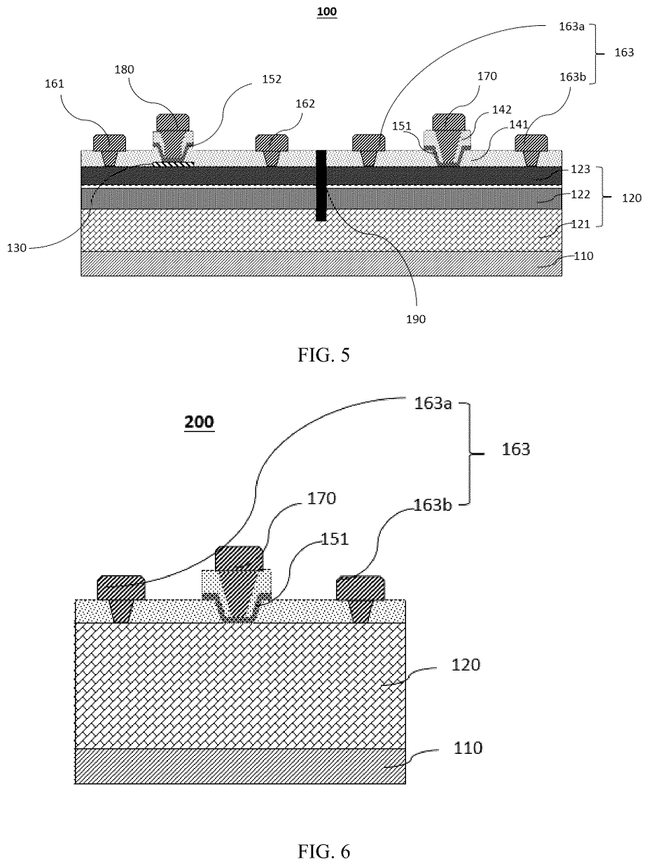

In some embodiments, referring to FIGS. 4-5, the first electrode 170 is provided with a bottom surface 170a disposed in the first via 141a and connected to the first n-type nitride layer 151, and two side surfaces 170b connected to the bottom surface 170a. An included angle between each of the two side surfaces 170b of the first electrode 170 and the surface of the compound semiconductor composite structure 120 is greater than an included angle between a corresponding one of the two sidewalls 141b of the first via 141a and the surface of the compound semiconductor composite structure 120. The integrated device 100 further includes a second dielectric layer 142, which is disposed between the first n-type nitride layer 151 and the two side surfaces 170b of the first electrode 170.

In order to match the existing electrode design of the second component 102 and save process steps, the design of the first n-type nitride layer 151 combined with the dielectric layers and the first electrode 170 enables the integrated device to have more stable performance and reduce costs thereof.

In some embodiments, referring to FIG. 1 and FIG. 2, in order to save process steps and form the integrated device 100 with stable properties, the dielectric layer (i.e., the second dielectric layer 142), the gate electrode 180, and the second n-type nitride layer 152 of the second component 102 are the same as the dielectric layer (i.e., the first dielectric layer 141), the first electrode 170, and the first n-type nitride layer 151 of the first component 101.

In some embodiments, as shown in FIG. 5, the integrated device 100 further includes an isolation layer 190. The isolation layer 190 at least extends from the surface of the compound semiconductor composite structure 120 to a side of the two-dimensional electron gas facing towards the substrate 110.

It should be noted that extending the isolation layer 190 to the side below the two-dimensional electron gas facing towards the substrate 110 refers to at least extending below the channel layer 122.

In order to prevent the first component 101 and the second component 102 from conducting laterally in the direction parallel to the substrate 110, the required functions of the integrated device can be achieved through external connections of the electrodes according to actual needs. The isolation layer 190 needs to be disposed at least below the channel layer 122 to isolate the first component 101 from the second component 102.

In an illustrated embodiment, as shown in FIG. 6, a Schottky diode 200 includes: a substrate 110; a compound semiconductor composite structure 120 disposed on the substrate 110; a first electrode 170 disposed on the compound semiconductor composite structure 120; and an n-type nitride layer 151 disposed between the compound semiconductor composite structure 120 and the first electrode 170.

The n-type nitride layer 151 disposed between the compound semiconductor composite structure 120 and the first electrode 170 can reduce the threshold voltage of the Schottky diode 200, and can reduce the power consumption of the component and improve the properties of the component.

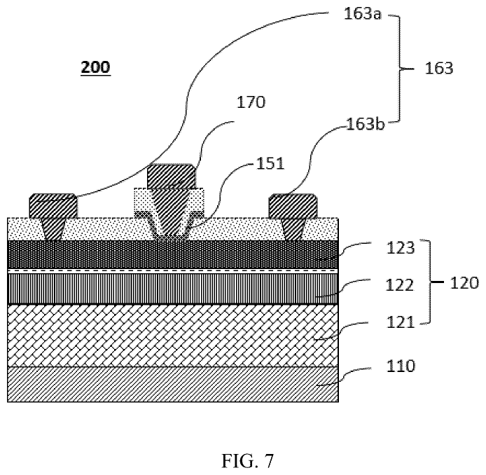

In some embodiments, as shown in FIG. 7, the compound semiconductor composite structure 120 includes a channel layer 122 and a barrier layer 123 disposed on the channel layer 122, and a contact area between the channel layer 122 and the barrier layer 123 is configured to generate a two-dimensional electron gas.

The Schottky diode 200 with the heterojunction formed by the barrier layer AlGaN and the channel layer GaN can improve the blocking voltage of the component and improve the properties of the component.

In some embodiments, the Schottky diode 200 further includes second electrodes 163 including the second electrode 163a and the second electrode 163b, and the second electrode 163a and the second electrode 163b are disposed on two sides of the first electrode 170.

It should be noted that the first electrode 170 is a positive electrode and the second electrode 163a and the second electrode 163b on the two sides of the first electrode 170 are negative electrodes, thereby forming a diode structure. The structure of the Schottky diode 200 is not strictly limited, and in the practical application, those skilled in the related art may design the diode structure according to requirements, as long as that the n-type nitride layer 151 capable of reducing the threshold voltage is formed between the first electrode 170 and the compound semiconductor composite structure 120.

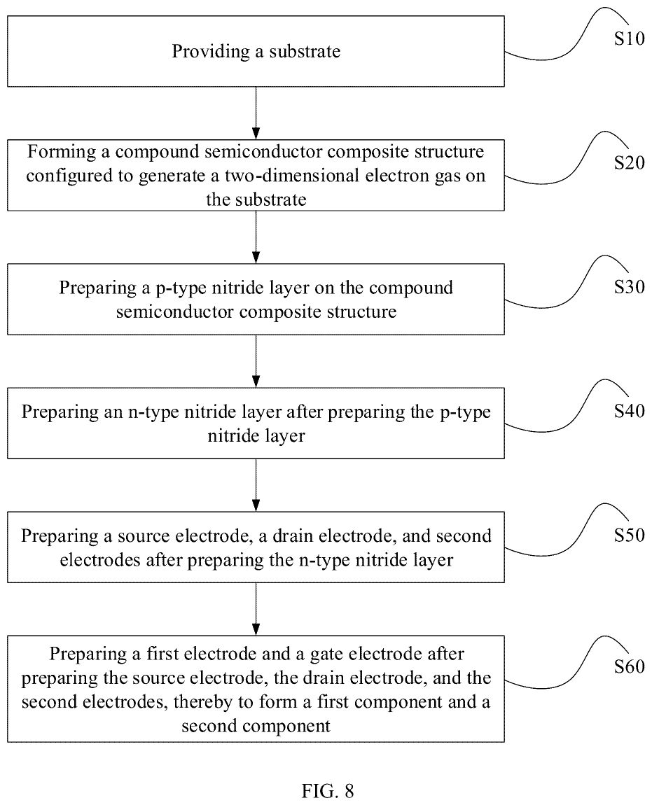

Another aspect of the embodiments of the present disclosure provides a method for preparing an integrated device, which is configured to prepare the integrated device 100. As shown in FIG. 8, the method for preparing the integrated device includes the following steps.

Step 10: a substrate 110 is provided. In the present embodiment, the substrate 110 is a silicon substrate. It should be noted that the silicon substrate is not limited to high resistance or low resistance, nor n-type or p-type.

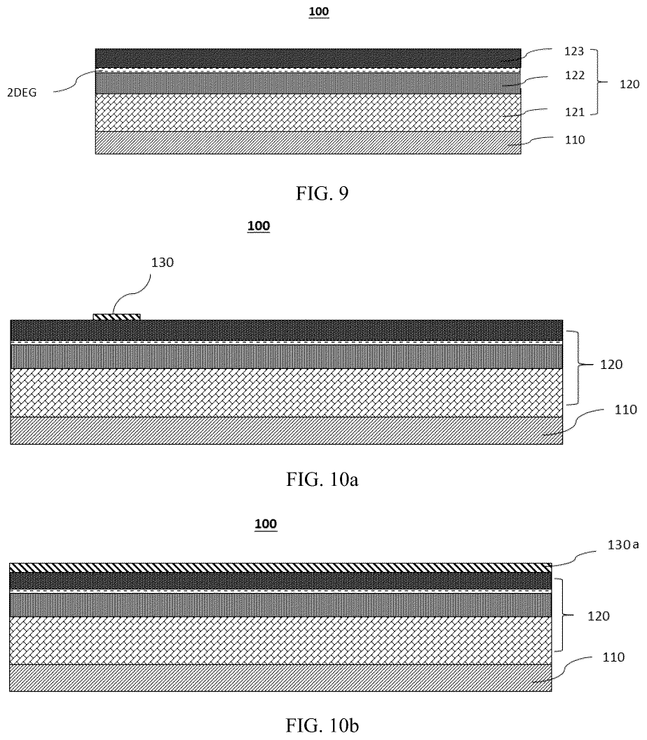

Step 20: as shown in FIG. 9, a compound semiconductor composite structure 120 generated with a two-dimensional electron gas 2DEG is formed on the substrate 110.

It should be noted that the compound semiconductor composite structure 120 generated with the two-dimensional electron gas 2DEG includes a back barrier layer and/or a buffer layer 121 disposed on the substrate 110, a channel layer 122, and a barrier layer 123, and the two-dimensional electron gas disposed between the channel layer 122 and the barrier layer 123. The compound semiconductor composite structure 120 can be designed by those skilled in the related art according to requirements for the integrated device.

Step 30: as shown in FIG. 10a, a p-type nitride layer 130 is prepared on the compound semiconductor composite structure 120.

The p-type nitride layer 130 is disposed between the compound semiconductor composite structure 120 and the gate electrode, thereby to form a second component with stable properties, it should be noted that the second component is a power component, and more specifically, the second component is an enhanced HEMT.

In some embodiments, referring to FIG. 10a and FIG. 10b, in order to enable the HEMT to have good properties, the step 30 of preparing the p-type nitride layer 130 includes: before preparing the n-type nitride layer 150, preparing a prefabricated p-type nitride layer 130a on the compound semiconductor composite structure 120, etching the prefabricated p-type nitride layer 130a to prepare the p-type nitride layer 130 disposed between the second n-type nitride layer 152 and the compound semiconductor composite structure 120.

In some embodiments, the step of preparing the p-type nitride layer 130 includes: preparing the prefabricated p-type nitride layer 130a on the compound semiconductor composite structure 120, covering a mask layer on the prefabricated p-type nitride layer 130a, defining a region of the p-type nitride layer 130 below the gate electrode 180 of the second component 102 in an exposure and development manner, removing the redundant mask layer in an etching manner, and finally removing the mask layer on the obtained p-type nitride layer 130, i.e., obtaining the p-type nitride layer 130. It should be noted that the preparation of the p-type nitride layer 130, the material of the mask layer, etc. are well known to those skilled in the related art, and the preparation method can be selected according to actual requirements, and details are not described herein again.

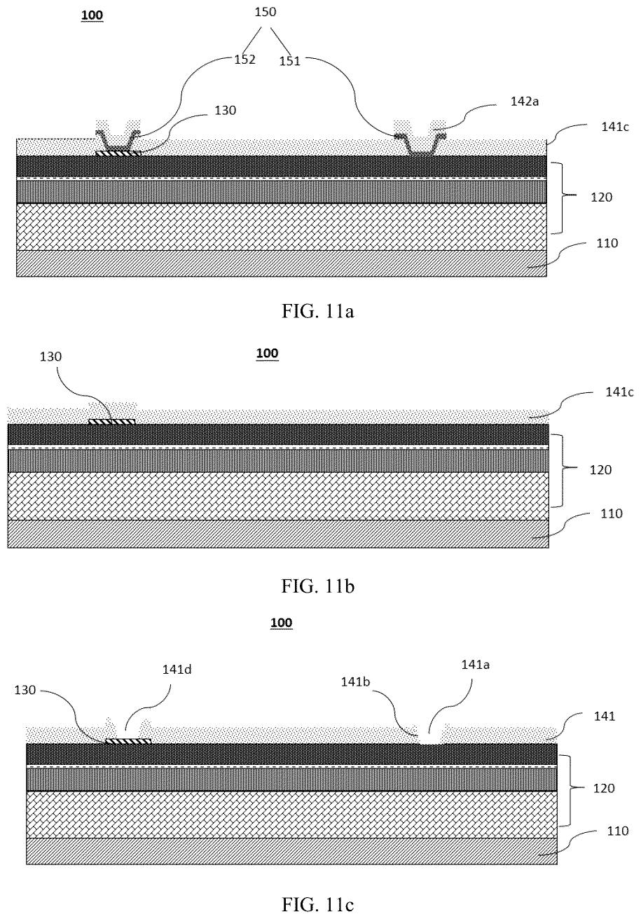

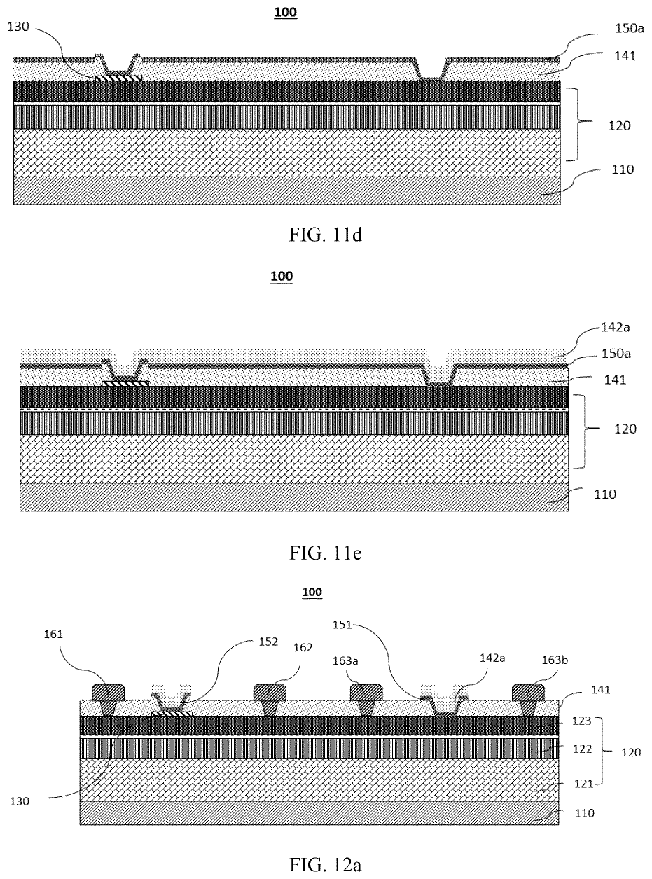

Step 40: as shown in FIG. 11a, the n-type nitride layer 150 is prepared after obtaining the p-type nitride layer 130.

The n-type nitride layer 150 includes a first n-type nitride layer 151, and the first n-type nitride layer 151 disposed between the compound semiconductor composite structure 120 and the first electrode 170 can reduce the threshold voltage of the first component, so that the integrated device 100 can be effectively turned on only by a small gate voltage, which can reduce the power consumption of the integrated device and improve the properties of the integrated device.

In some embodiments, the n-type nitride layer 150 further includes a second n-type nitride layer 152 disposed between the p-type nitride layer 130 and the gate electrode 180, and the second n-type nitride layer 152 is capable of forming the heterojunction with the p-type nitride layer 130, thereby reducing the leakage of the integrated device and enhancing stability of the gate control.

In some embodiments, as shown in FIGS. 11a-11e, the step of preparing the n-type nitride layer 150 includes: preparing a first prefabricated dielectric layer 141c on the compound semiconductor composite structure 120 (with reference to FIG. 11b), and etching the first prefabricated dielectric layer 141c to define a first via 141a for accommodating the first electrode 170 and a second via 141d for accommodating the gate electrode 180 (with reference to FIG. 11c); preparing a prefabricated n-type nitride layer 150a on the first prefabricated dielectric layer 141c (with reference to FIG. 11d), preparing a second prefabricated dielectric layer 142a on the prefabricated n-type nitride layer 150a (with reference to FIG. 11e), etching the second prefabricated dielectric layer 142a and the prefabricated n-type nitride layer 150a, thereby obtaining the first n-type nitride layer 151 between the first via 141a and the second prefabricated dielectric layer 142a, and the second n-type nitride layer 152 between the second via 141d and the second prefabricated dielectric layer 142a (with reference to FIG. 11a).

In the preparation method of the n-type nitride layer 150, an n-type GaN layer is respectively grown on the gate electrode of the second component and the first electrode of the first component, so that the preparation efficiency is improved, the preparation process is simplified, the cost can be better reduced, the two components have high consistency, and the function of synchronously optimizing the properties of the first component and the second component can be achieved. It should be noted that the first component is the power diode, and more specifically, the first component is a Schottky diode.

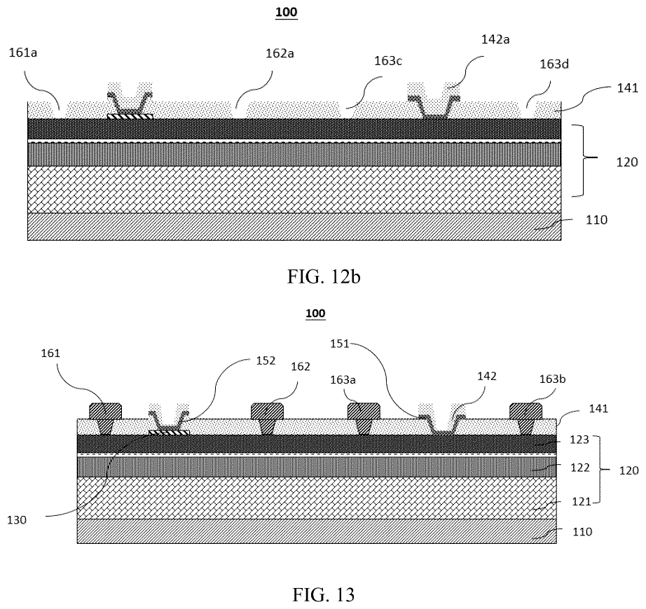

Step 50: as shown in FIG. 12a, a source electrode 161, a drain electrode 162, and a second electrode 163a and a second electrode 163b are prepared after obtaining the n-type nitride layer 150.

In order to form a monolithic integration of the first component and the second component suitable for batch production, having advantages such as small volume and light weight, the source electrode 161, the drain electrode 162, the second electrode 163a and the second electrode 163b are disposed on the first dielectric layer 141.

In some embodiments, referring to FIG. 12a and FIG. 12b, in order to form a good ohmic electrode contact of the integrated device 100, the step of preparing the second electrode 163a and the second electrode 163b, the source electrode 161, and the drain electrode 162 includes: after the step of preparing the n-type nitride layer 150, etching the first prefabricated dielectric layer 141c to define a first groove 163c, a second groove 163d, a third groove 161a, and a fourth groove 162a, thereby obtaining the first dielectric layer 141. Moreover, a metal layer is prepared on the first dielectric layer 141, and then the second electrode 163a and the second electrode 163b are formed in the first groove 163c and the second groove 163d, respectively, the source electrode 161 is formed in the third groove 161a, and the drain electrode 162 is formed in the fourth groove 162a.

Step 60: as shown in FIG. 2, after the source electrode 161, the drain electrode 162, the second electrode 163a, and the second electrode 163b are prepared, the first electrode 170 and the gate electrode 180 are prepared to obtain the first component 101 and the second component 102.

In order to form the monolithic integration of the first component 101 and the second component 102 suitable for batch production, having advantages such as small volume and light weight, realize the reduction in the threshold voltage of the first component 101 and the optimization of the properties of the integrated device 100, the first electrode 170 is disposed on the first n-type nitride layer 151, and the gate electrode 180 is disposed on the second n-type nitride layer 152.

In some embodiments, referring to FIGS. 11a-11e, FIG. 12a, and FIG. 13, in order to form the well contact for the Schottky diode to obtain the integrated device 100 with stable properties, and the steps of preparing the first electrode 170 and the gate electrode 180 include: etching the second prefabricated dielectric layer 142a disposed in the first via 141a and the second via 141d to obtain the second dielectric layer 142 accommodating the first electrode 170 and the gate electrode 180, and preparing another metal layer on the second dielectric layer 142 to obtain the first electrode 170 and the gate electrode 180.

In some embodiments, as shown in FIG. 2 and FIG. 5, the method for preparing the integrated device 100 further includes: preparing an isolation layer 190. The isolation layer 190 at least extends from the surface of the compound semiconductor composite structure 120 to a side of the two-dimensional electron gas facing towards the substrate 110, and is configured to isolate the first component 101 from the second component 102.

It should be noted that the isolation layer 190 extends to the side facing towards the substrate 110 below the two-dimensional electron gas, which refers to at least extending below the channel layer 122. In order to prevent the first component 101 and the second component 102 from conducting laterally in the direction parallel to the substrate 110, the required functions of the integrated device can be achieved through external connections of electrodes according to actual needs. The isolation layer 190 needs to be disposed at least below the channel layer 122.

In some embodiments, specially, the isolation layer 190 is formed by ion implantation, table etching, or a combination of the above-mentioned processes to isolate the first component 101 from the second component 102 after the first component 101 and the second component 102 are formed. Those skilled in the related art can choose the preparation method of the isolation layer 190 according to actual needs, as long as it can isolate the first component 101 from the second component 102.

The above only describes the illustrated embodiments of the present disclosure, but the scope of the protection of the present disclosure is not limited thereto. Those skilled in the related art may easily make changes or replacements within the technical scope of the present disclosure, and such changes or replacements are intended to be within the scope of the protection of the present disclosure. Therefore, the scope of the protection of the present disclosure shall be subject to the disclosure. As long as there is no structural conflict, all the technical features mentioned in the embodiments can be combined in any manner. The present disclosure is not limited to the illustrated embodiments disclosed herein, but includes all technical solutions falling within the scope of the present disclosure.

What is claimed is:

1. An integrated device, comprising:
a substrate;
a compound semiconductor composite structure, disposed on the substrate and configured to generate a two-dimensional electron gas;
a first component, comprising a first electrode and second electrodes disposed on two sides of the first electrode;
a second component, comprising a gate electrode, a source electrode, and a drain electrode, wherein the source electrode and the drain electrode are disposed on two sides of the gate electrode; and the first electrode and the gate electrode are spaced apart on the compound semiconductor composite structure;
a negative-type (n-type) nitride layer, comprising a first n-type nitride layer, wherein the first n-type nitride layer is disposed between the compound semiconductor composite structure and the first electrode; and
a positive-type (p-type) nitride layer, disposed between the compound semiconductor composite structure and the gate electrode.

2. The integrated device as claimed in claim 1, wherein the n-type nitride layer further comprises a second n-type nitride layer, and the second n-type nitride layer is disposed between the p-type nitride layer and the gate electrode.

3. The integrated device as claimed in claim 2, further comprising: a first dielectric layer, disposed on the compound semiconductor composite structure; and
wherein the first dielectric layer defines a first via, the first via is configured to accommodate the first electrode, the first via is provided with two sidewalls facing towards a surface of the compound semiconductor composite structure, and the first n-type nitride layer extends from the two sidewalls of the first via to the surface of the compound semiconductor composite structure disposed in the first via.

4. The integrated device as claimed in claim 3, wherein the first electrode is provided with a bottom surface disposed in the first via and connected to the first n-type nitride layer, and two side surfaces connected to the bottom surface of the first electrode;
wherein an included angle between each of the two side surfaces of the first electrode and the surface of the compound semiconductor composite structure is greater than an included angle between a corresponding one of the two sidewalls of the first via and the surface of the compound semiconductor composite structure; and
wherein the integrated device further comprises: a second dielectric layer, and the second dielectric layer is disposed between the first n-type nitride layer and the two side surfaces of the first electrode.

5. The integrated device as claimed in claim 4, further comprising: an isolation layer, wherein the isolation layer at least extends from the surface of the compound semiconductor composite structure to a side of the two-dimensional electron gas facing towards the substrate.

6. The integrated device as claimed in claim 5, wherein a shape of the first n-type nitride layer disposed in the first component is the same as a shape of the second n-type nitride layer disposed in the second component; and/or
wherein a shape of the first electrode disposed in the first component is the same as a shape of the gate electrode disposed in the second component.

7. The integrated device as claimed in claim 1, wherein each of the first component and the second component further comprises a first dielectric layer, and the first dielectric layer of the first component is located in a same layer as the first dielectric layer of the second component.

8. The integrated device as claimed in claim 4, wherein the first dielectric layer further defines a second via configured to accommodate the gate electrode, the second via exposes the p-type nitride layer, the second n-type nitride layer covers sidewalls of the second via and a surface of the p-type nitride layer exposed by the second via, and the gate electrode is disposed in the second via.

9. The integrated device as claimed in claim 8, wherein the second dielectric layer is further disposed between the second n-type nitride layer and the sidewalls of the second via.

10. A Schottky diode, comprising:
a substrate;
a compound semiconductor composite structure, disposed on the substrate;
a first electrode, disposed on the compound semiconductor composite structure; and
an n-type nitride layer, disposed between the compound semiconductor composite structure and the first electrode.

11. The Schottky diode as claimed in claim 10, wherein the compound semiconductor composite structure comprises: a channel layer and a barrier layer located on the channel layer, and a contact area between the channel layer and the barrier layer is configured to generate a two-dimensional electron gas.

12. The Schottky diode as claimed in claim 11, further comprising second electrodes, wherein the second electrodes are disposed on two sides of the first electrode.

13. The Schottky diode as claimed in claim 10, further comprising: a first dielectric layer, disposed on the compound semiconductor composite structure; and
wherein the first dielectric layer defines a via configured to accommodate the first electrode, the via is provided with two sidewalls facing towards a surface of the compound semiconductor composite structure, and the n-type nitride layer extends from the two sidewalls of the via to the surface of the compound semiconductor composite structure disposed in the via.

14. The Schottky diode as claimed in claim 13, wherein the first electrode is provided with a bottom surface disposed in the via and connected to the n-type nitride layer, and two side surfaces connected to the bottom surface of the first electrode;
wherein an included angle between each of the two side surfaces of the first electrode and the surface of the compound semiconductor composite structure is greater than an included angle between a corresponding one of the two sidewalls of the via and the surface of the compound semiconductor composite structure; and
wherein the Schottky diode further comprises: a second dielectric layer, disposed between the n-type nitride layer and the two side surfaces of the first electrode.

15. A method for preparing an integrated device, comprising:
providing a substrate;
forming a compound semiconductor composite structure configured to generate a two-dimensional electron gas on the substrate;
forming a first component and a second component on the compound semiconductor composite structure, wherein the first component comprises: a first electrode and second electrodes disposed on two sides of the first electrode; the second component comprises: a gate electrode, a source electrode, and a drain electrode, and the source electrode and the drain electrode are disposed on two sides of the gate electrode; and the first electrode and the gate electrode are spaced apart on the compound semiconductor composite structure;
preparing an n-type nitride layer, wherein the n-type nitride layer comprises: a first n-type nitride layer, and the first n-type nitride layer is disposed between the compound semiconductor composite structure and the first electrode; and
preparing a p-type nitride layer, wherein the p-type nitride layer is disposed between the compound semiconductor composite structure and the gate electrode.

16. The method for preparing the integrated device as claimed in claim 15, wherein the preparing an n-type nitride layer comprises:
preparing a first prefabricated dielectric layer on the compound semiconductor composite structure, and etching the first prefabricated dielectric layer to define a first via configured to accommodate the first electrode and a second via configured to accommodate the gate electrode; and
preparing a prefabricated n-type nitride layer on the first prefabricated dielectric layer, preparing a second prefabricated dielectric layer on the prefabricated n-type nitride layer, etching the second prefabricated dielectric layer and the prefabricated n-type nitride layer to obtain the first n-type nitride layer between the first via and the second prefabricated dielectric layer, and to obtain a second n-type nitride layer between the second via and the second prefabricated dielectric layer.

17. The method for preparing the integrated device as claimed in claim 16, wherein the preparing a p-type nitride layer comprises:
before preparing the n-type nitride layer, preparing a prefabricated p-type nitride layer on the compound semiconductor composite structure, etching the prefabricated p-type nitride layer to obtain the p-type nitride layer disposed between the second n-type nitride layer and the compound semiconductor composite structure.

18. The method for preparing the integrated device as claimed in claim 17, wherein the second electrodes, the source electrode, and the drain electrode are prepared according to the following steps:
after the n-type nitride layer is prepared, etching the first prefabricated dielectric layer to define a first groove, a second groove, a third groove, and a fourth groove, thereby obtaining the first dielectric layer;
preparing a first metal layer on the first dielectric layer, forming the second electrodes in the first groove and the second groove, respectively, forming the source electrode in the third groove, and forming the drain electrode in the fourth groove.

19. The method for preparing the integrated device as claimed in claim 18, wherein the first electrode and the gate electrode are prepared according to the following steps:
etching the second prefabricated dielectric layer in the first via and the second via to obtain a second dielectric layer configured to accommodate the first electrode and the gate electrode; and
preparing a second metal layer on the second dielectric layer to obtain the first electrode and the gate electrode.

20. The method for preparing the integrated device as claimed in claim 15, further comprising: preparing an isolation layer, wherein the isolation layer at least extends from a surface of the compound semiconductor composite structure to a side of the two-dimensional electron gas facing towards the substrate, and is configured to isolate the first component from the second component.
